(19) United States
(12) Patent Application Publication
(10) Pub. No.: US 2002/0190769 A1
(43) Pub. Date: Dec. 19, 2002

(54) Biased hysteretic systems

(75) Inventors: Norman William Schubring, Troy, MI (US); Joseph Vito Mantese, Shelby Twp., MI (US); Adolph Louis Micheli, Harrison Twp., MI (US)

Correspondence Address: RADER, FISHMAN & GRAUER PLLC, 39533 WOODWARD AVENUE, SUITE 140, BLOOMFIELD HILLS, MI, 48304-0610, US

(73) Assignee: Delphi Technologies, Inc.

(21) Appl. No.: 10/170,858

(22) Filed: Jun. 13, 2002

Related U.S. Application Data
(60) Provisional application No. 60/297,986, filed on Jun. 13, 2001.

(51) Int. Cl. H03K 3/13; H03K 3/02

(52) U.S. Cl. 327/205; 330/3

(57) ABSTRACT

An apparatus for generating an amplified effect in an asymmetrical hysteretic system is disclosed. The asymmetrical hysteretic system comprises a transponent, a bias that externally grades the transponent, an energy source that drives the transponent, and a small stimulus amplified by a gain factor of the transponent. A method for generating an amplified effect in an asymmetrical hysteretic system is also disclosed.

### RELATED APPLICATIONS

This application claims priority to U.S. Provisional Application No. 60/297,986 filed Jun. 13, 2001.

### TECHNICAL FIELD

The present invention relates to asymmetrical hysteretic systems. More specifically, the present invention relates to asymmetrical hysteretic systems that have an amplified effect in response to a periodic stimulation.

### BACKGROUND OF THE INVENTION

Hysteretic systems can inherently store energy during and after an applied stimulation. The systems are regarded as being symmetrical in nature and perfectly balanced in response to a stimulus. It was surmised that a balanced hysteresis loop of a hysteretic system was the ideal form; any system that exhibited a deviation from a balanced hysteresis loop was considered to have an error, or an unknown, uninteresting, and valueless characteristic. For example, ferroelectrics that exhibit any asymmetry of a response (charge) to a stimulus (voltage) was usually attributed to simple non-ohmic contacts at the electrode interface surfaces. Generally, the asymmetrical ferroelectric devices were declared imperfect and disregarded.

Such ferroelectrics, which may be employed as a transducer shown generally at 160 in FIG. 16, are typically internally graded in composition and exhibit an asymmetrical hysteresis loop. The ferroelectric 160 exhibits an internal voltage V_{FE} and an internal voltage, V_{DC}. The internal voltage, V_{DC}, arises from the internal gradation of the ferroelectric 160. The unforeseen advantage in such asymmetry for a ferroelectric hysteretic system is that it generates a usable amplified effect that may be expedited by a periodic stimulus. This is achieved by internally (i.e. functionally) grading the system. Ferroelectrics may have an internal gradient in: voltage, temperature, strain, electric field, or any combination thereof.

In the example discussed above for FIG. 16, the amplified effect of the hysteretic system is a result of its internal gradation of the ferroelectric. However, it is contemplated by the applicants that the gradient of all hysteretic systems (e.g. dielectric, magnetic, mechanical, chemical, biological, optical, electrical, thermal, acoustical, astronomical, environmental, etc.) may be alternatively achieved in order to produce the amplified effect. Therefore, it is an objective of the applicants to show that any hysteretic system having asymmetry in its hysteresis loop will generate a useable amplified effect that may be expedited when a periodic stimulus (ii) is applied to an externally graded (i.e. externally biased) hysteretic system.

### SUMMARY OF THE INVENTION

Accordingly one embodiment of the invention is directed to an asymmetrical hysteretic system comprising a transponent, a bias that externally grades the transponent, an energy source that drives the transponent, and a small stimulus amplified by a gain factor of the transponent.

Another embodiment of the invention is directed to an asymmetrical hysteretic system comprising a transponent, a bias that externally grades the transponent, an energy source defined by a periodic stimulus that drives the transponent, and a small stimulus that is amplified by a gain factor of the transponent. The gain factor is approximately one-half the quantity of a DC stimulus multiplied by a DC response.

Another embodiment of the invention is directed to a method for generating an amplified effect for an asymmetrical hysteretic system. The asymmetrical hysteretic system comprises a transponent, a bias, a periodic stimulus, and a small stimulus. The method comprises the steps of grading the transponent with the bias, driving the transponent with the periodic stimulus, generating a gain factor in response to the periodic stimulus driving the transponent, amplifying the small stimulus with the gain factor, and producing an amplified output defined by the small stimulus and the gain factor.

### BRIEF DESCRIPTION OF THE DRAWINGS

The present invention will now be described, by way of example, with reference to the accompanying drawings, in which:

FIG. 1 is a graphical representation of a system having a single linear response to a single linear stimulus;

FIG. 2 is a graphical representation of a bilateral system having a single linear response to a single linear stimulus;

FIG. 3 is a graphical representation of a bilateral-nonlinear system having a single non-linear response to a single linear stimulus;

FIG. 4 is a graphical representation of a nonlinear, irreversible system having non-linear responses to a single linear stimulus;

FIG. 5 is a graphical representation of a full cycle, nonlinear, irreversible system having non-linear responses to a single linear stimulus;

FIG. 6A is a graphical representation of a hysteretic system defined by an asymmetrical hysteresis loop;

FIG. 6B is a graphical representation of an initial asymmetrical hysteretic system that ultimately transitions to a symmetrical hysteresis loop having an amplified effect;

FIG. 7 is a representative diagram of an asymmetrical hysteretic system comprising a transponent;

FIG. 8A is a series circuit including a biased dielectric hysteretic system comprising a biased ferroelectric transducer;

FIG. 8B is a graphical representation of the amplified effect of the biased dielectric hysteretic system of FIG. 8A;

FIG. 9A is a representation of a biased magnetic hysteretic system;

FIG. 9B is a graphical representation of the amplified effect of the biased magnetic hysteretic system of FIG. 9A;

FIG. 10A is a representation of a biased mechanical hysteretic system;

FIG. 10B is a graphical representation of the amplified effect of the biased mechanical hysteretic system of FIG. 10A;

FIG. 11A is a representation of another biased mechanical hysteretic system;

FIG. 11B is a graphical representation of the amplified effect of the biased mechanical hysteretic system of FIG. 11A;

FIG. 12A is a representation of another biased mechanical hysteretic system;

FIG. 12B is a graphical representation of the amplified effect of the biased mechanical hysteretic system of FIG. 12A;

FIG. 13A is a representation of a biased biological hysteretic system;

FIG. 13B is a graphical representation of the amplified effect of the biased biological hysteretic system of FIG. 13A;

FIG. 14A is a representation of a biased chemical hysteretic system;

FIG. 14B is a graphical representation of the amplified effect of the biased chemical hysteretic system of FIG. 14A;

FIG. 15A is a representation of a biased optical hysteretic system;

FIG. 15B is a graphical representation of the amplified effect of the biased optical hysteretic system of FIG. 15A; and

FIG. 16 is a series circuit including an internally graded dielectric hysteretic system comprising an internally graded ferroelectric transducer.

### DESCRIPTION OF THE PREFERRED EMBODIMENT

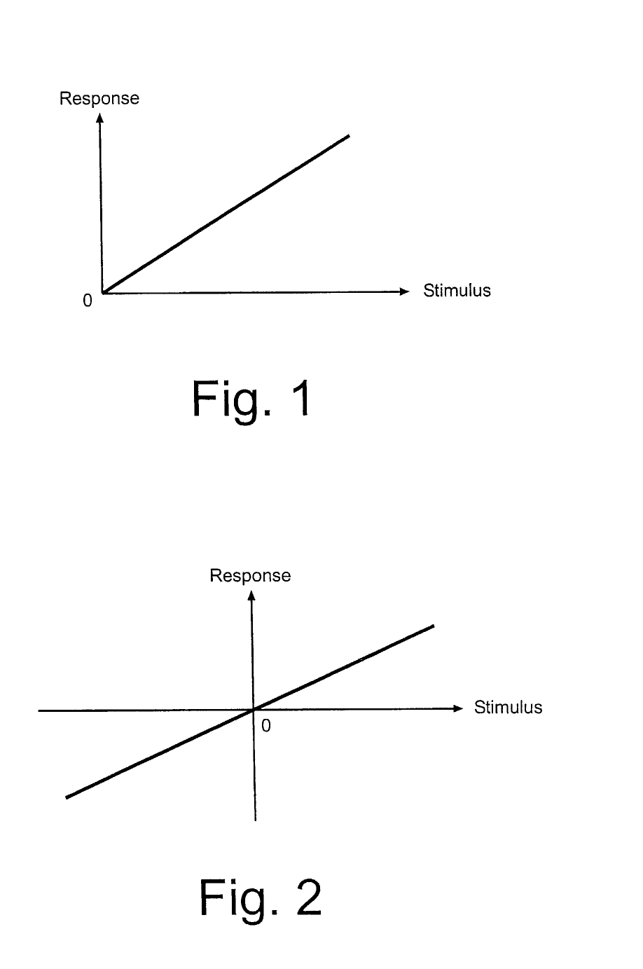

To understand where asymmetrical hysteretic systems fit in the progress of the complexity of the following applications, a brief synopsis is in order. Referring to FIG. 1, any system shall always have at least one stimulus (represented on the x-axis) and one response (represented on the y-axis). For some degree of complexity, there may be multiple stimuli x(n), and/or multiple responses y(n), where n is an integer of one or more.

The integral of x*dy on an x-y plot is an area, which must necessarily represent a form of energy of some type (e.g. mechanical, electrical, magnetic, thermal, optical, acoustical, chemical, etc.). Because total energy is constant, all that can be done in a system is the movement of energy in one form or another. However, any energy movement always involves a cost. Some of the system's energy is exploited to reposition the remaining energy, or to change its form. In the case of a hysteretic system involving an external stimulus, such as an external power supply, the external power supply is usually considered to be an unaccountable “x source.”

The energy stored in a linear system may be a direct function of the stimulus source; when the stimulus is zero no energy stored. As shown in FIG. 1, there is basically a single, linear, unilateral response to a single, linear stimulus. As shown in FIG. 2, if the system is bilateral, the behavior is balanced. Because stimulus is the independent variable, the energy of the system is always

{Stimulus d(Response)}.

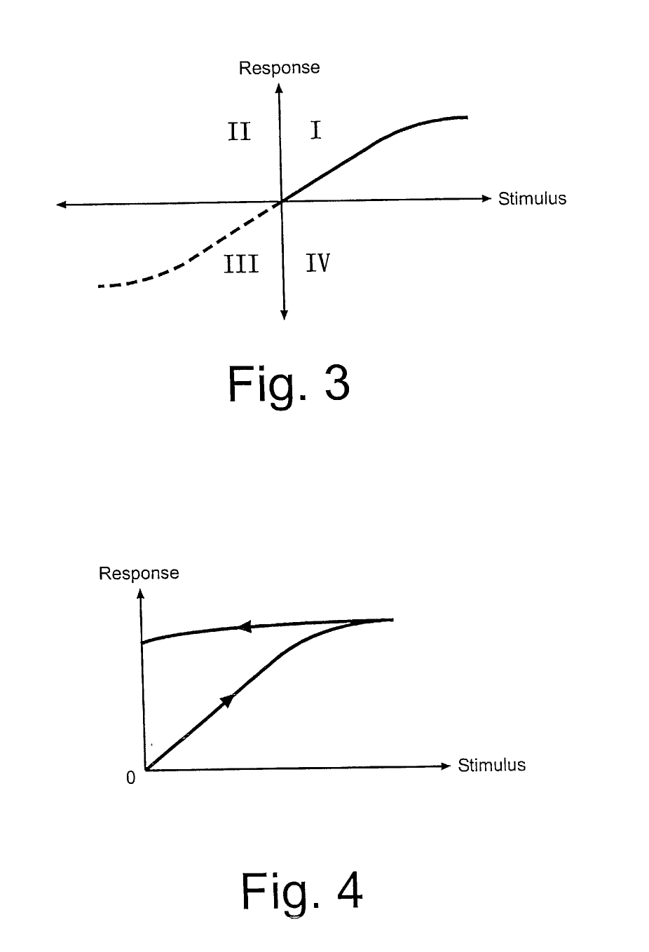

This fact becomes very important for the higher order, nonlinear, irreversible systems. As shown in FIG. 3, if the system is more complex, there may be nonlinearity or saturation in the first quadrant (I), or the first and third quadrants (I, III).

As seen in FIG. 4, the system may also be nonlinear and irreversible. Irreversibility means that the system cannot retrace the path in reverse, but will seek a new path and never return to zero at the zero stimulus. In this case, all the energy is not returned in retreating to the origin, but rather, it is stored in the system. The stored energy is an inherent quality of the system to statically store energy by remembering the last stimulus.

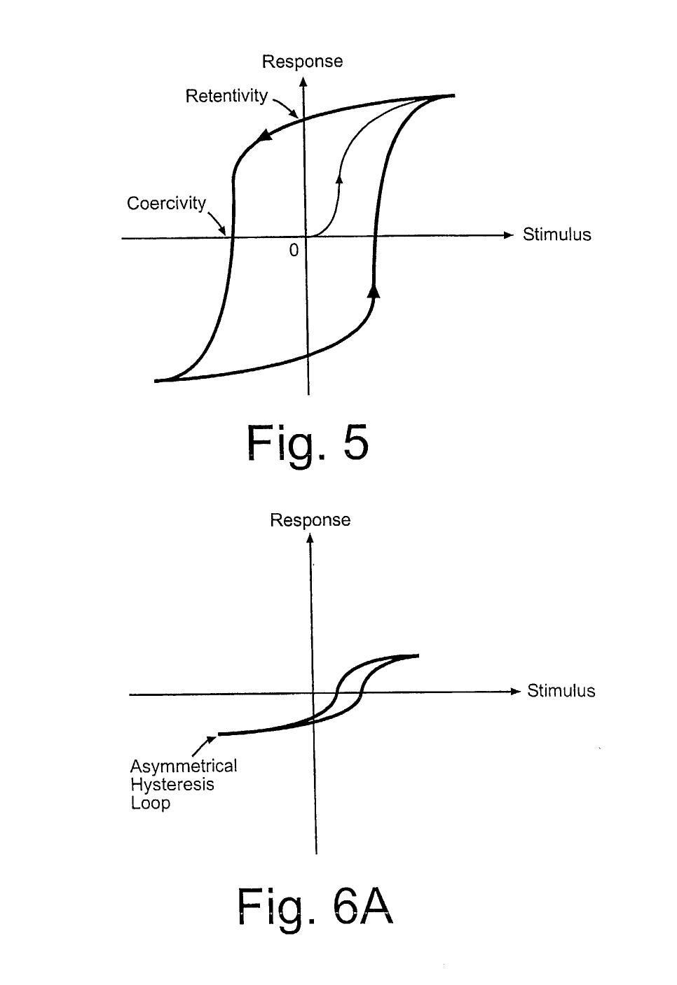

To complete the progression of symmetrical hysteretic systems, a full cycle, nonlinear, irreversible system is shown in FIG. 5. When the system is initially at rest and fully neutralized, a given stimulus creates an initial response that starts from the origin. However, once stimulated, the system memorizes the last stimulus, and retains some discrete values of the response.

For a single stimulus, the typical hysteresis is always counterclockwise. However, for multiple stimuli, the loop can be forced to reverse directions and go clockwise in the foregoing analysis. In a counterclockwise travel, the hysteresis indicates energy drawn into the system. For a clockwise travel, energy is released by the system. The only basic requirement is that the system can be able to permanently store energy. The latter portrayal constitutes all symmetrical hysteresis systems, where the response is not only nonlinear, but irreversible.

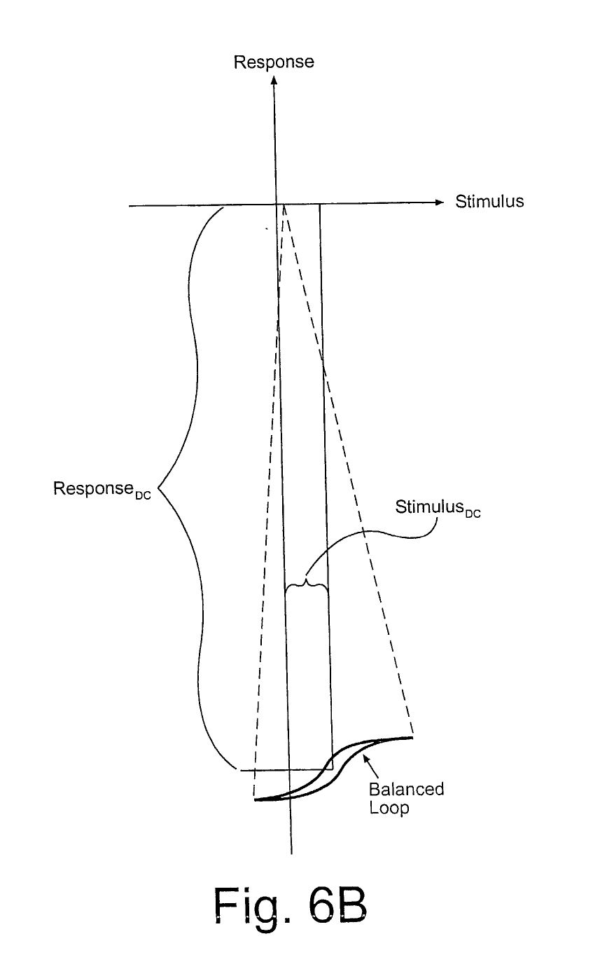

Referring now to FIGS. 6A and 6B, asymmetrical hysteretic systems that include an external bias develop a significant amplified effect and results in hysteresis asymmetry. In FIG. 6A, an instantaneous hysteresis loop for an asymmetrical system is idealized with a slight shift in the positive x-direction. The shift defines the external bias (i.e. an external stimulus) included in the system. For example, before a ferroelectric material is excited by a periodic stimulus, the ferroelectric material is influenced by an external stimulus, such as a DC voltage. Thus, in the absence of even exciting an asymmetrical system with the periodic stimulus, a graphical depiction of an instantaneous hysteresis loop is shown shifted (FIG. 6A) in the positive x-direction so as to define the external bias that influences the system. When driven by a symmetrical periodic excitation, the area of the asymmetrical hysteresis loop in quadrants I and IV is much greater than the area in quadrants II and III. Thus, the asymmetrical hysteresis loop is defined by an unbalanced storage of energy because the area of the loop in unbalanced.

In FIG. 6B, once the periodic stimulus is applied to the system, an amplified effect in the negative y-direction (response) arises. The amplified effect may be static in nature and very useable in response to the periodic stimulus. The overall shift in the x- and y-direction that defines the amplified effect is identified by a DC stimulus and a DC response. The amplified effect, which is hereinafter referred to as the gain factor (GF), is an area defined by:

GF=½(Stimulus_{DC}*Response_{DC}).

The GF amplification is very large and is graphically defined by an inversion of a negative slope (y=−mx+b). In an electrical sense, the GF amplification acts like a negative capacitor akin to a negative resistor in an active ohm's law device. However, it is important to note that the analogy to a negative capacitor does not limit the invention to electrical asymmetrical hysteretic systems, but rather, to all hysteretic systems that exhibits asymmetry.

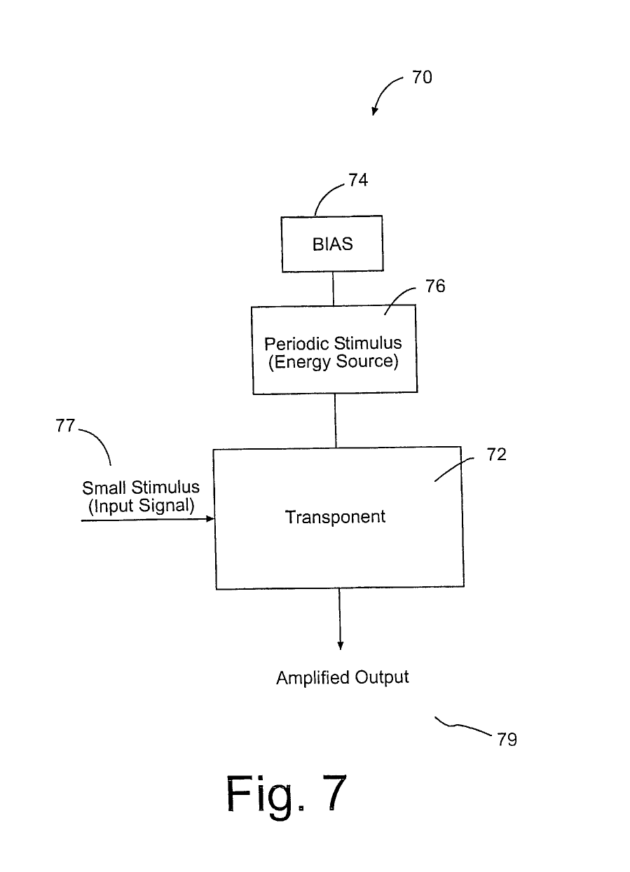

The physical representation of FIGS. 6A-6B is seen in FIG. 7. A transponent 72 sets the GF of an asymmetrical hysteretic system 70. The transponent 72 is part of an externally-graded (i.e. externally biased) structure comprising a bias 74 and an energy source, such as a periodic stimulus 76. The bias 74 is a generally large, external stimulus that grades the hysteretic system 70, thus, eliminating the need for internally-graded materials in the hysteretic system 70. In some instances, the bias 74 is generally considered to be so large that it overwhelms the periodic stimulus 76. A small stimulus 77, such as an input signal, may be fed into the transponent 72. However, it is important to note that the small stimulus 77 may not necessarily be an input signal, and may be internally contained within the transponent 72 in the form of a small amount of internal energy. As described above in FIG. 6B, the amplified effect is expedited by the periodic stimulus 76, thus producing an amplified output 79 (e.g. a quantity of energy) defined by the GF (i.e. the system sources energy). The amplification is called a “transponent action.”

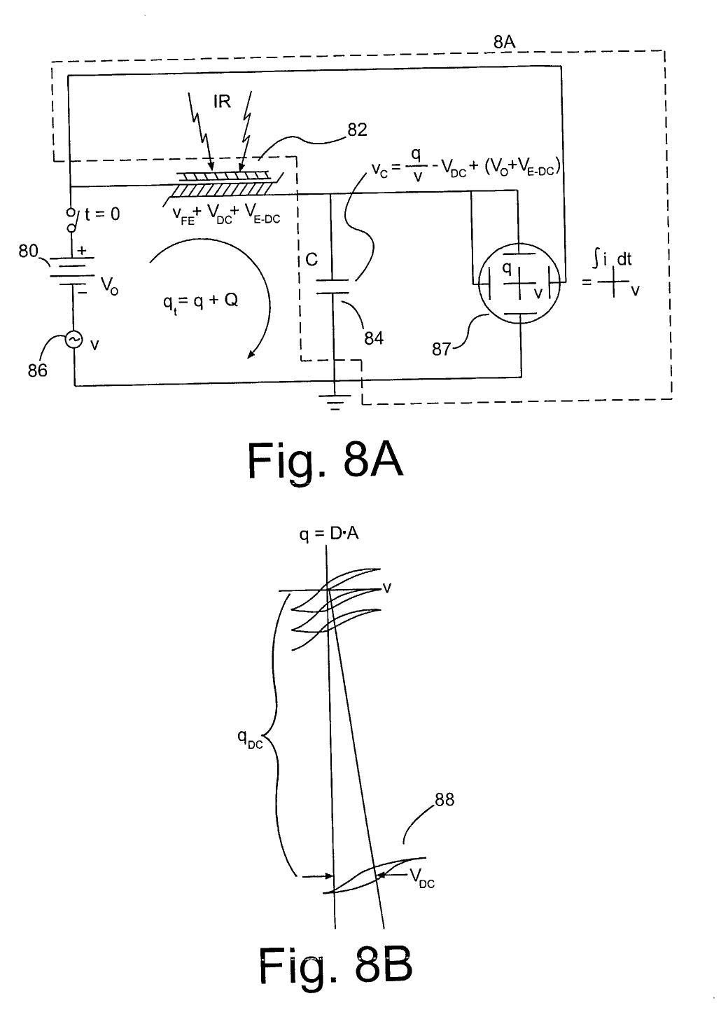

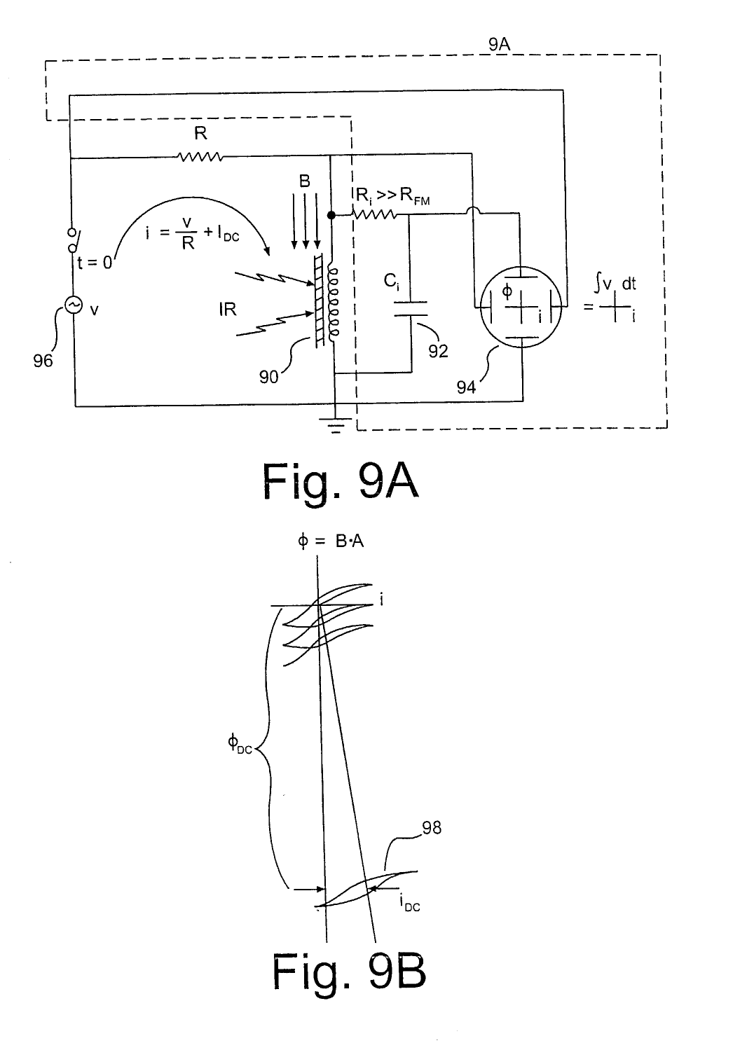

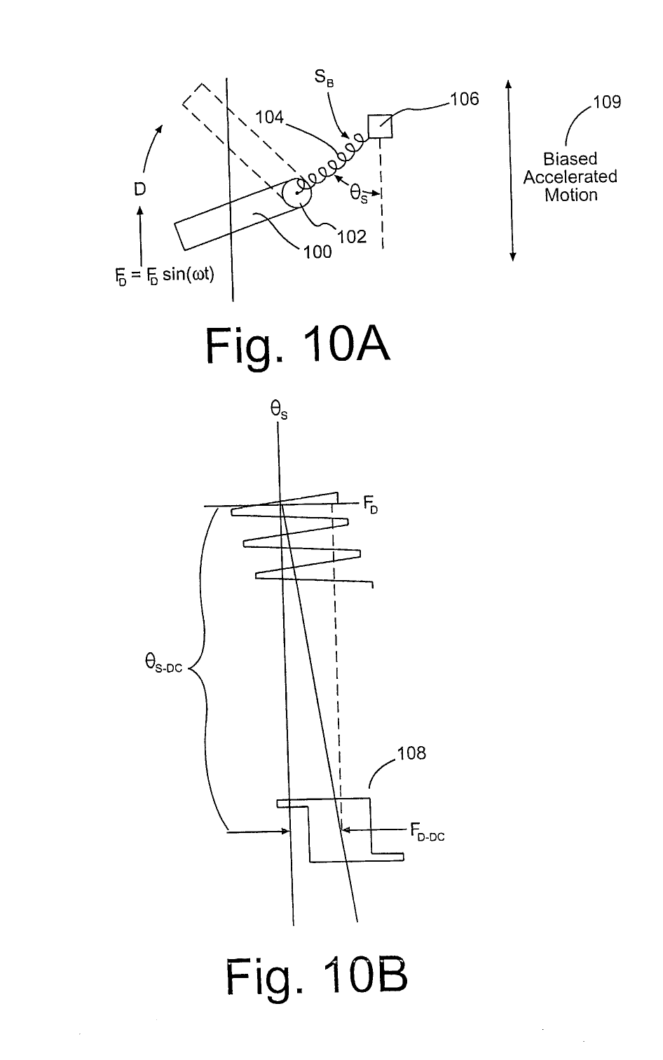

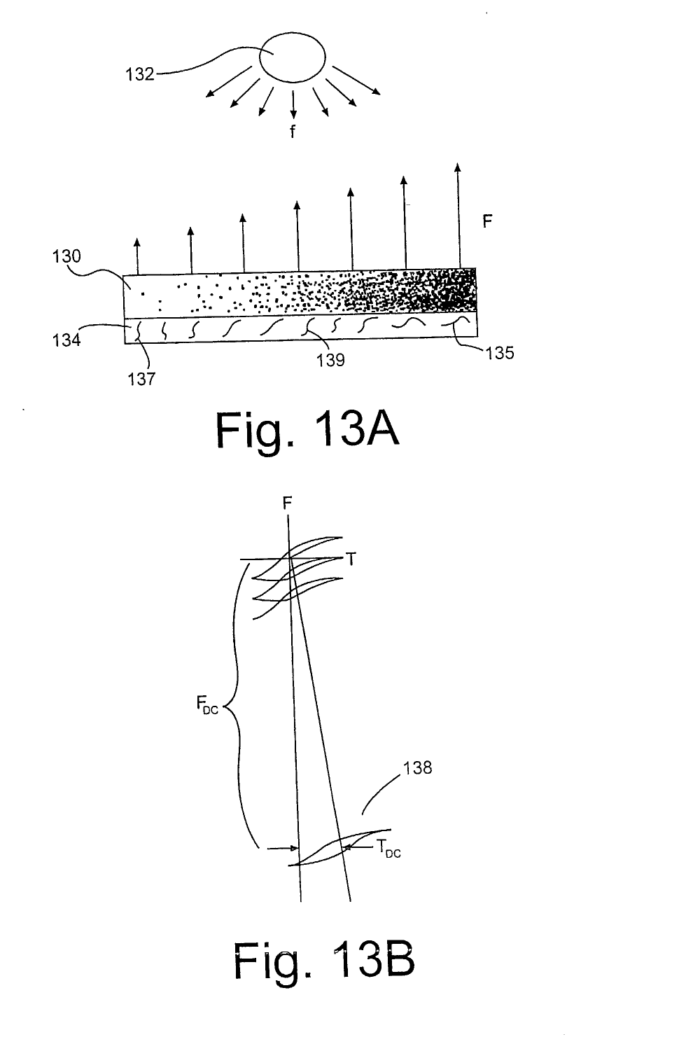

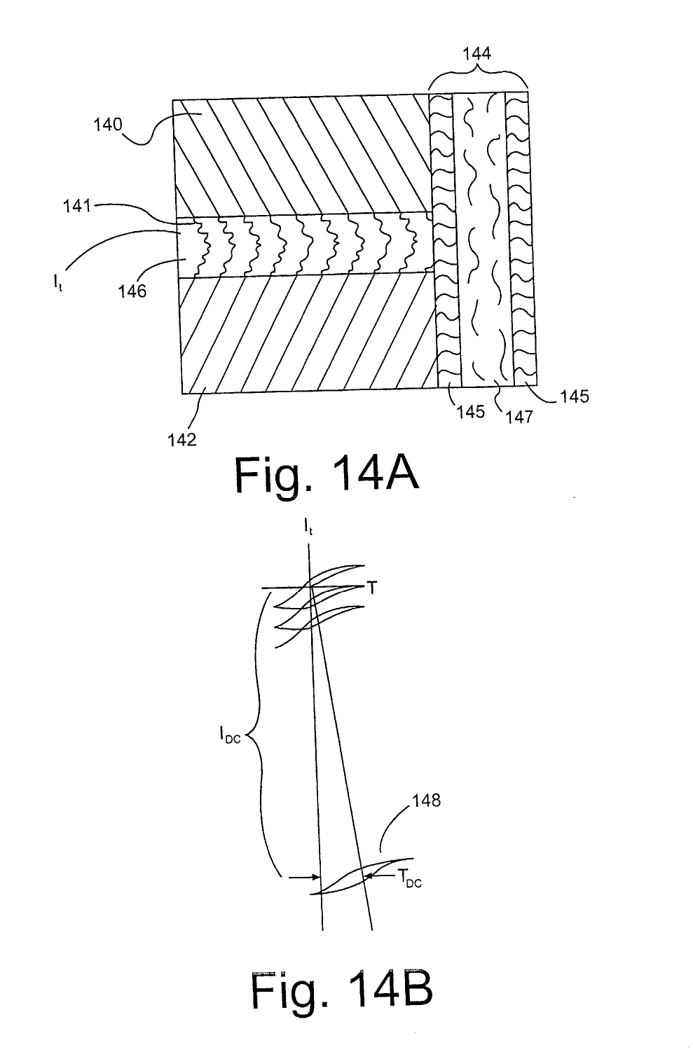

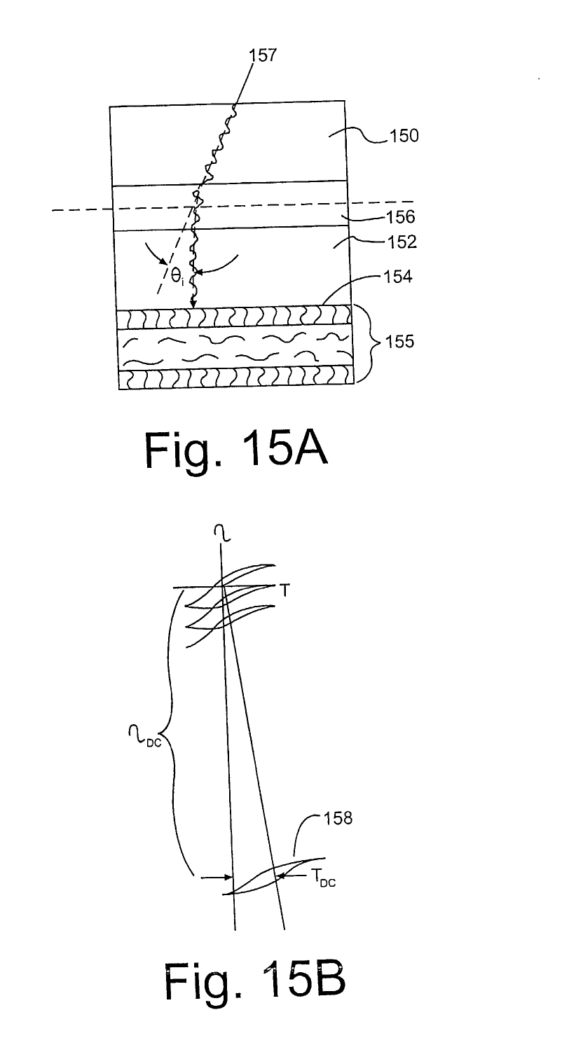

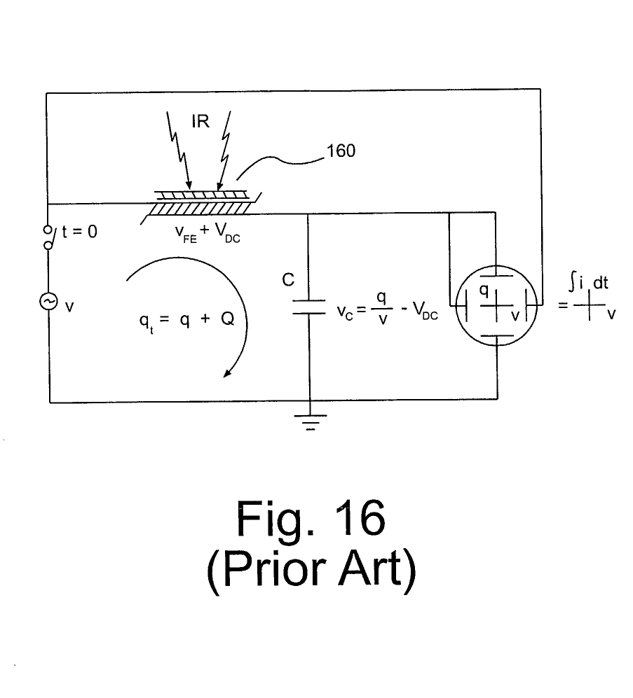

The transponent action is dependant upon the external gradation of the system and may result from any small stimulus 77 such as voltage, current, force, heat, temperature, strain, etc. The amplified output 79 may be charge, magnetic flux, position movement, fluorescence, strain, etc. Thus, the transponent action may apply to any biased asymmetrical hysteretic system of all types of energy including: dielectric systems (FIG. 8A), magnetic systems (FIG. 9A), mechanical systems (FIGS. 10A-12A), chemical systems (FIG. 13A), biological systems (FIG. 14A), optical systems (FIG. 15A), or any combination thereof with either static or dynamic stimulus (ii). Other biased hysteretic systems may also include: electrical, thermal, acoustical, environmental, astronomical, etc.

As seen in FIG. 8A, an externally biased electric field ferroelectric transducer is realized and thus eliminates the need for an internally-graded ferroelectric. A static offset in polarization, which relies upon hysteresis loop asymmetry, coupled with active AC operation, is accomplished with plain homogenous ferroelectrics simultaneously. The externally biased electric field ferroelectric transducer is an ideal transducer that is based on the principles of compositionally graded ferroelectrics by incorporating a DC polarization offset. When driven by a symmetrical alternating excitation, the plus and minus areas on opposite sides of the asymmetrical hysteresis loop (i.e. the variance in loop area of quadrants I and IV compared to II and III in FIG. 6A) have different voltage values upon AC excitation (i.e. the loop is asymmetrical and is defined by an unbalanced storage of energy). Consequently, there is a net polarization in one direction. Thus, the DC polarization offset biases the system and externally grades the ferroelectric transducer.

By introducing the concept of a DC bias offset 80 having a voltage, Vₒ, which is regarded as zero impedance, to a symmetrical ferroelectric transducer 82, the hysteresis loop can be forced to go asymmetrical (FIG. 8B). The circuitry, as seen in FIG. 8A, is a simple series connection of the DC bias offset 80, an asymmetrical ferroelectric transducer 82, and a charge sensing capacitor 84 across a source of AC excitation with zero DC impedance 86. The voltage seen across the ferroelectric transducer 82 shows a fractional voltage, V_{E-DC}, of the bias voltage, Vₒ, that arises from the external gradation of the system. The portion of the circuit that measures the ferroelectric transducer 82 is defined by a dashed line 8A and includes an oscilloscope 87 connected in parallel with the charge sensing capacitor 84. In such an arrangement, the oscilloscope 87 provides a load when it is connected in parallel with the charge sensing capacitor 84, a low- or zero-impedance alternating source 86, and the ferroelectric transducer 82.

As seen in FIG. 8B, a graphical representation of the stimulus (voltage, v) plotted against the response (charge, q) is measured by the oscilloscope 87 and represented by a balanced hysteresis loop 88. It is apparent that the hysteresis loop 88 develops a translation along the vertical axis, such as an amplified effect approximately equivalent to q_{DC}, and a lateral translation from its centroid position near the origin approximately equivalent to V_{DC}. The gain factor of the system is:

GF=½(V_{DC}*q_{DC}).

Thus, the GF for the system is an amplified energy that would allow one to get a DC control of the response (q_{DC}) and use it for a sensor, such as a pyroelectric detector for night vision, or telecommunications, such as tunable filter materials for frequency delineation. The system described above is based on the principles of graded ferroelectric materials, such as transpacitors and other graded ferroelectric devices, that are influenced by a third source of energy. However, a similar result is achieved by externally grading the ferroelectric material.

As seen in FIG. 9A, a biased magnetic system in a circuit comprised of a ferromagnetic device 90 is connected in parallel with an integrating capacitor 92 and the resistor, R₁. The portion of the circuit that measures the ferromagnetic device 90 is defined by a dashed line 9A and includes an oscilloscope 94 connected in parallel with the integrating capacitor 92. In such an arrangement, the oscilloscope 94 provides a significant resistance and has a high impedance load when it is connected in parallel with the integrating capacitor 92, a low- or zero-impedance alternating source 96, and the ferromagnetic device 90.

The system described above is based on the principles of ferromagnetic materials, such as transductors and other ferromagnetic devices, that may be influenced by an external bias, such as an external magnetic field, B, acting upon the ferromagnetic device 90. The devices may be applied to sensors, such as ultra-sensitive magnetometers and position sensors, or telecommunications, such as tunable resonators and circulators.

As seen in FIG. 9B, a graphical representation of the stimulus (current, i) plotted against the response (flux, Φ) is measured by the oscilloscope 94 and represented by a balanced hysteresis loop 98. When the flux, Φ, is measured, it will be weak and noisy. Therefore, an active current, i, is chosen for overcoming the noise. It is apparent that the hysteresis loop 98 develops a translation along the vertical axis, such as an amplified effect approximately equivalent to Φ_{DC}, and a lateral translation from its centroid position near the origin approximately equivalent to i_{DC}. The gain factor for the system is

GF=½(i_{DC}*Φ_{DC}).

Thus, the GF for the system is an amplified energy that would allow one to get a DC control of the response (Φ_{DC}) and use it for a sensor, such as an ultra-sensitive magnetometer or position sensor, or in telecommunications, such as a tunable resonator or circulator.

As seen in FIG. 10A, a biased mechanical system in the form of a mechanical switch comprises a toggle switch 100, a pivot point 102, an internal spring 104 having an angular dependant spring force bias, S_{B}, and a spring coupler 106. The spring force bias, S_{B}, relates to a spring constant, k, of the material, which also relates to the internal energy, E, of the spring including a position variable, x, of the switch (S_{B}=E=½ kx²). The position variable of the switch, x, can have two different, stable positions being a down position (shown by a solid line for switch 100), or an up position (shown by a dotted line for switch 100). The positioning variable, x, is further related to the angle of the spring, θₛ, which varies during movement of the switch 100.

In such an arrangement, the toggle switch 100 exhibits an asymmetrical hysteresis through an externally biased accelerated motion 109 of the mechanical system. The accelerated motion may travel in a single direction that either is with or opposes the direction of movement, D, of the switch 100. Because the toggle switch 100 is biased in one direction corresponding to the biased accelerated motion 109, it operates either coercively or resistively when applying the direction of movement, D, with an oscillating force defined by F_{D}=Fₒ sin(ωt) from a motor (not shown). Thus, the biased accelerated motion 109 can either hinder or aid the movement of the toggle switch 100.

The system described above is based on the principles of energy (i.e. energy as a function of an accelerated motion) that has a gradient in force or potential. This particular biased mechanical system may apply in an accelerated environment such as in a car or rocket. In other words, the advantage is not the snap action of the toggle switch 100, but rather the controlled movement of the toggle switch 100 in an accelerated environment.

As seen in FIG. 10B, a graphical representation of the stimulus (oscillating force, FD) plotted against the response (angle of the spring, θₛ) is represented by a balanced hysteresis loop 108. It is apparent that the hysteresis loop 108 develops a translation along the vertical axis, such as an amplified effect approximately equivalent to θ_{s-DC}, and a lateral translation from its centroid position near the origin approximately equivalent to F_{D-DC}. The gain factor for the system is

GF=½(F_{D-DC}*θ_{s-DC}).

Thus, the GF for the system is an amplified energy that would allow one to get a DC control of the response (θ_{s-DC}) and use it in a positioner application in an accelerated environment.

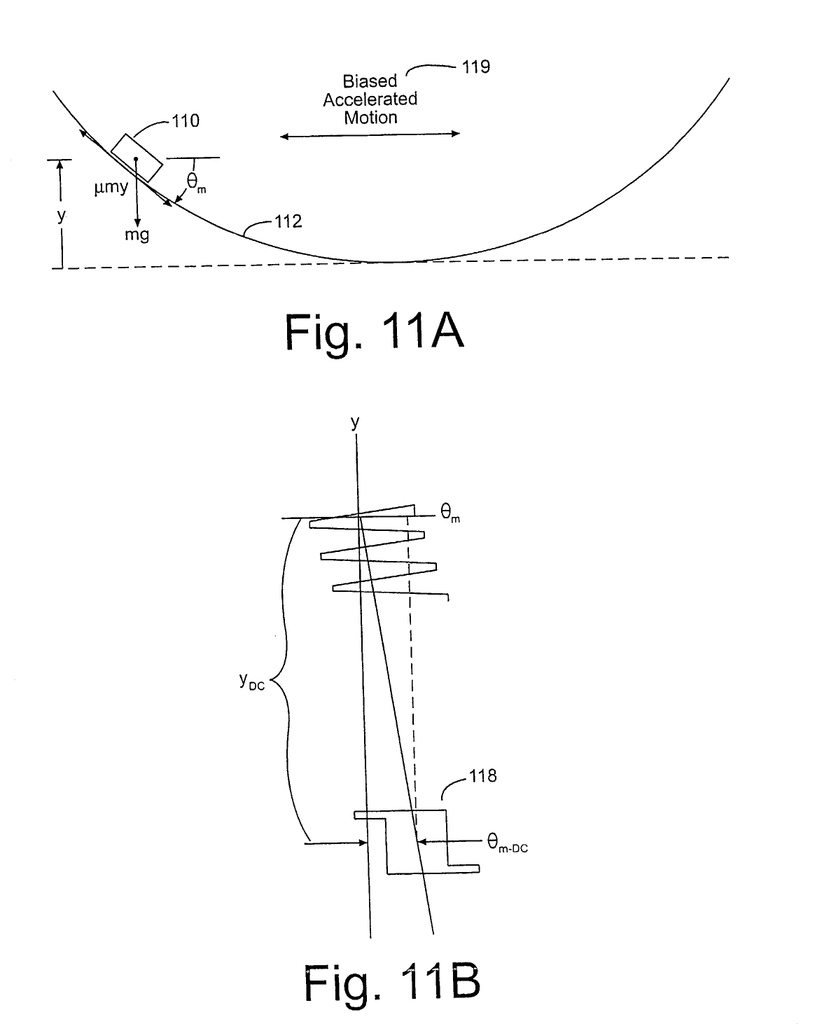

As seen in FIG. 11A, another biased mechanical system in the form of a mass (m) 110 appears on a sloping surface 112, such as a bowl. The gradient of this system is an externally biased accelerated motion 119 in a single direction. Because the system is externally graded by the biased accelerated motion 119, it is asymmetrical and incorporates the motion of the mass 110.

The system described above is based on the principles of energy (i.e. energy as a function of accelerated motion) that has a gradient in force or potential. The system may be applied to a mass that is set at the threshold of static position. A symmetrical stimulus, such as an acceleration provided by gravity, g, acts as an amplifier. The acceleration provided by gravity, g, and the coefficient of friction, μ, operating on the mass (μmg) is constant. However, the acceleration provided by gravity, g, and the coefficient of friction, μ, operating on the mass is dependant upon the slope of the surface 112 at a particular point.

As seen in FIG. 11B, a graphical representation of the stimulus (angle of the mass 110 on the slope, θₘ) plotted against the response (vertical distance, y) is represented by a balanced hysteresis loop 118. Because there is a difference between static friction and sliding friction, if the mass 110 is moved back and forth and up and down, it will gradually oscillate in movement until it comes to a stop. The uphill movement of the mass 110 exhibits the asymmetrical hysteretic behavior expressed in the hysteresis loop 118. It is apparent that the hysteresis loop 118 develops a translation along the vertical axis, such as an amplified effect approximately equivalent to y_{DC}, and a lateral translation from its centroid position near the origin approximately equivalent to θ_{m-DC}. The gain factor for the system is

GF=½(θ_{m-DC}*y_{DC}).

Thus, the GF for the system is an amplified energy that would allow one to get a DC control of the response (y_{DC}) and use it in a positioning application that is set at the threshold of static position of a mass.

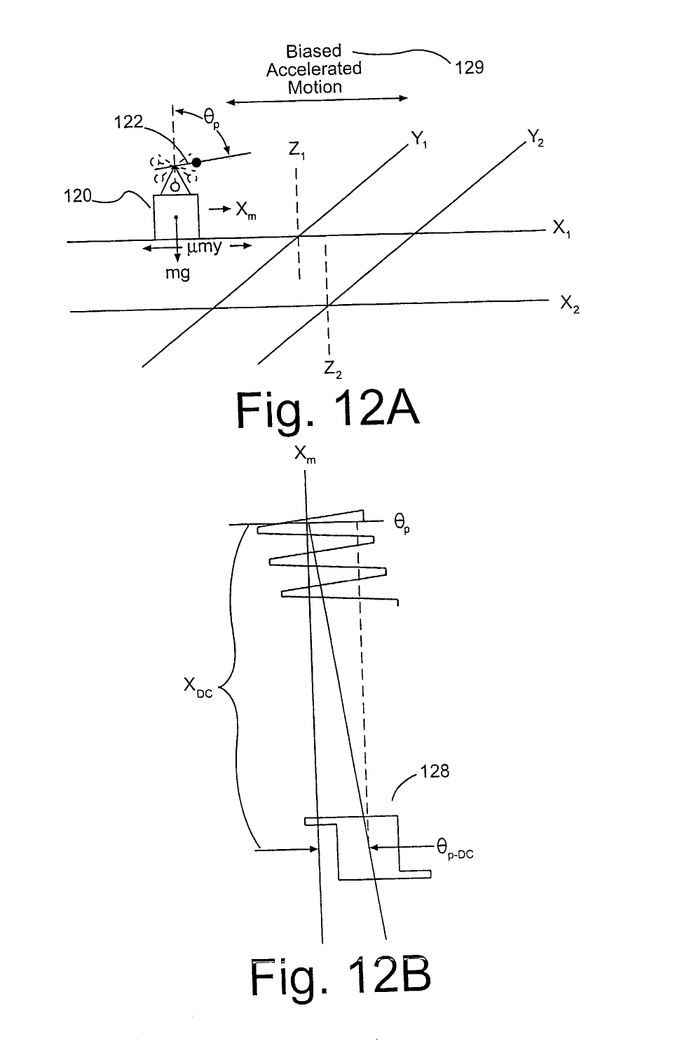

As seen in FIG. 12A, another biased mechanical system comprises a mass (m) 120 with a moveable pendulum 122. The gradient of this system is an externally biased accelerated motion 129 in a single direction. The mass 120 is located on a level surface X₁, so that is may move in a specified direction via the oscillatory movement of the pendulum 122. The pendulum 122 oscillates such that the mass 120 moves very slightly so that it creeps along the surface gradation of the level surface, X₁. Because the system is externally graded by the biased accelerated motion 129, it is asymmetrical and incorporates the motion of the mass 120.

The periodic stimulus is the pendulum 122, which for all practical purposes continues perpetually after being energized. The pendulum 122 represents an internal or external weight of the mass 120 that moves back and forth. The mass 120 is defined to be lighter than that of the pendulum 122. The overall extent of the weight difference between the mass 120 and pendulum 122 translates into the movement of the mass 120. Although a pendulum 122 is generally shown as the source of movement for the mass 120, the pendulum 122 may be an internal or external oscillator in the mass 120 that allows it to creep along towards its final position.

The system described above is based on the principles of energy (i.e. energy as a function of accelerated movement) that has a gradient in force or potential. The mechanical system may be applied to situations requiring precision control adjustments, such as positioning alignment. In the present system, a vertical force (mg) on the mass 120 that is below the threshold of sliding friction (μmg) is augmented by the oscillatory force of the pendulum 122. In this way, the system described above permits precision control alignment of a plane Z₁ with a plane Z₂. The advantage for this system is that real, exact positioning may be achieved by taking advantage of the energy that is stored in the pendulum 122.

Even though the system described above may be implemented for larger scale systems, the mass 120 and pendulum 122 may be very small such that they are designed to a microscale for a system that requires micropositioning. For example, in the semiconductor industry, the mass 120 may align planes Z₁, Z₂ in the range of microns, or even sub-microns, such as a quarter micron or two-tenths of a micron. This is accomplished by the very precise motion of the pendulum 122.

As seen in FIG. 12B, a graphical representation of the stimulus (angle of the pendulum, θₚ) plotted against the response (movement of the mass, Xₘ) is represented by a balanced hysteresis loop 128. It is apparent that the hysteresis loop 128 develops a translation along the vertical axis, such as an amplified effect approximately equivalent to X_{DC}, and a lateral translation from its centroid position near the origin approximately equivalent to θ_{p-DC}. X_{DC} is the position of the mass, and θ_{p-DC} is an internal definition of movement that the pendulum operates at. The gain factor for the system is

GF=½(θ_{p-DC}*X_{DC}).

Thus, the GF for the system is an amplified energy that would allow one to get a DC control of the response (X_{DC}) and use it in a positioning application, such as micropositioning for a semiconductor.

As seen in FIG. 13A, a biased biological system comprises a unit of cells 130, a light source 132, and a temperature plate 134. In this system, the cells 130 are located over a horizontal plate, such as the temperature control plate 134, which is hereinafter referred to as a hot plate 134. The hot plate 134 may cycle through hot and cold temperatures, which are defined by a hot zone having horizontal lines 135 and a cold zone having vertical lines 137. The middle portion of the hot plate 134 is a neutral zone that is neither hot or cold and is defined by diagonal lines 139. The hot plate 134 drives the system and represents the periodic stimulus by providing a gradient in temperature, T, with an external bias, T₂, (i.e. a DC temperature constant). The gradient in temperature, T, is approximately equivalent to T=T₁ sin(ωt)+T₂.

The system described above is based on the principles of biological activity. As shown above, the temperature gradient forms a gradient in the biological system, such as a gradient in biological activity. The biological activity is defined by a change in fluorescence intensity, F=Fₒ sin(ωt), of the system having a periodic value. According to the FIG. 13A, the biological system tends to have a greater fluorescence at higher temperatures and a lower fluorescence at lower temperatures. As will be seen below, the temperature gradient causes the hot zone of the cells 130 to fluoresce more than the cold zone when they are struck with light, from the light source 132 having an incident flux with a periodic modulation, f=fₒ(sin(ωt).

The fluorescence, F, is a function of temperature and the incident flux, f. For example, when the temperature is lowered, the cells 130 shut down and the fluorescence, F, degrades to a larger degree. Conversely, when the temperature is raised slightly, the cells 130 become active and have a higher degree of fluorescence, F, under the incident flux, f. Other sources of light and heat may also contribute to the fluorescence, F, to some degree.

The system described above may be applied to cells 130 that fluoresce and that have a function of thermal energy, chemical energy, or some other form of energy. For example, if biological cells 130 are sensitive to a specific chemical environment, a certain drug may affect the fluorescence, F, of the cells 130 so that it may be detectable. If the fluorescence, F, that is detected, one can determine the amount of chemical existence in the biological cell 130. In another application, biological cells 130 may be killed with a form of radiation. If the net fluorescence, F, is identified, then the correct amount of radiation dosage can be determined for a specified amount of biological cells 130 that relate to the detected fluorescence, F.

As seen in FIG. 13B, a graphical representation of the stimulus (temperature of the hot plate, T) plotted against the response (fluorescence of the cells, F) is represented by a balanced hysteresis loop 138. The intensity of the fluorescence, F, may be measured by a charge-coupled detector. It is apparent that the hysteresis loop 138 develops a translation along the vertical axis, such as an amplified effect approximately equivalent to F_{DC}, and a lateral translation from its centroid position near the origin approximately equivalent to T_{DC}, the internal temperature of the system. The gain factor for the system is

GF=½(T_{DC}*F_{DC}).

Thus, the GF for the system is an amplified energy that would allow one to get a DC control of the response (F_{DC}) and use it in a biological application that has fluorescing cells that are excited by thermal energy or chemical energy.

As seen in FIG. 14A, a biased chemical system comprises a first chemical 140, a second chemical 142, and a hotplate 144. The chemicals 140, 142 are located adjacent to the hotplate 144. Similar to the biological embodiment described above in FIG. 13A, the hot plate 144 may cycle through hot and cold temperatures which are defined by a hot zone 145 comprising horizontal lines and a cold zone 147 comprising vertical lines. The hot plate 144 drives the system and represents the periodic stimulus by providing a gradient in temperature, T, with an external bias, T₂, (i.e. a DC temperature constant). The gradient in temperature, T, is approximately equivalent to T=T₁ sin(ωt)+T₂.

The first chemical 140 and the second chemical 142 may be, for example, methanol and gasoline, respectively. The chemicals 140, 142 have different densities and a miscibility that is a function of temperature. At high temperatures, the chemicals 140, 142 are completely miscible. At low temperatures, the two chemicals 140, 142 are phase separated by an interface 146 where the chemicals 140, 142 are inter-diffused and tend to rest on top of each other. Generally, the interdiffusion chemicals 140, 142 is defined by the sharpness of the lines 141 in the interface 146. The interdiffusion 141 depends upon the overall temperature of the hot plate 144.

When the hot plate 144 cycles the temperature of the system, the interface 146 will change in size from large to small. The thickness, It, of the interface 146 is a function of the temperature and the effects of gravity, g, on the chemicals 140, 142. The local chemical energy content, ψ=ψₒ(g, Tₒ(sin(ωt)), is a function of temperature, Tₒ, and the characteristics of the chemical constituents 140, 142. Locally, the chemical concentration in the interface 146 determines the chemical reactivity.

The system described above is based on the principles of chemical reactivity. An application of this system may be used to detect temperature or a third chemical that dramatically changes the properties of the interface region 146. The oscillating of the temperature in the system is not limited to a sinusoidal drive in temperature with a bias, but may be any periodic function with a bias.

As seen in FIG. 14B, a graphical representation of the stimulus (temperature of the hot plate, T) plotted against the response (interface thickness, Iₜ) is represented by a balanced hysteresis loop 148. It is apparent that the hysteresis loop 148 develops a translation along the vertical axis, such as an amplified effect approximately equivalent to I_{DC}, and a lateral translation from its centroid position near the origin approximately equivalent to T_{DC}, the internal temperature of the system. The gain factor for the system is

GF=½(T_{DC}*I_{DC}).

Thus, the GF for the system is an amplified energy that would allow one to get a DC control of the response (I_{DC}) and use it in a chemical application for detecting either temperature or a third chemical that dramatically changes the properties of an interface region of interacting chemicals.

As seen in FIG. 15A, a biased optical system comprises a first medium 150, a second medium 152, and an interface 154, which is adjacent to a hot plate 155. The first medium 150 and the second medium 152 may be, for example, a liquid and a chemical, respectively, that have different modulations. Similar to the chemical system in FIG. 14A, the mediums 150, 152 have different densities and miscibilities that are a function of temperature, T. The hot plate 154 drives the system and represents the periodic stimulus by providing a gradient in temperature, T, with an external bias, T₂, (i.e. a DC temperature constant). The gradient in temperature, T, is approximately equivalent to T=T₁ sin(ωt)+T₂.

In this system, the mediums 150, 152 are located above the interface 154 and interact in a miscible zone 156. The miscible zone 156 is the gradient of the system in that it is a function of the temperature gradient of the hot plate interface 154. A light-ray 157, such as a laser beam, is scanned into the mediums 150, 152 that refracts at an angle, θᵢ, which results in the light-ray 157 being incident upon the interface 154.

The index of refraction, η, is a function of the two mediums 150, 152, and the miscibility zone 156. Thus, the miscible zone 156 determines the index of refraction, η, at which the light-ray 157 bends, and the mediums 150, 152 determines the velocity at which the light-ray 157 travels through the mediums 150, 152.

The system described above is based on the principles of chemical reactivity. The system may be applied to any device that requires modulation of the index of refraction, η, or the mediums that define the device to affect optical transmission or reflection (e.g. an oscillating prism).

As seen in FIG. 15B, a graphical representation of the stimulus (temperature of the hot plate, T) plotted against the response (index of refraction, η) is represented by a balanced hysteresis loop 158. It is apparent that the hysteresis loop 158 develops a translation along the vertical axis, such as an amplified effect approximately equivalent to η_{DC}, and a lateral translation from its centroid position near the origin approximately equivalent to T_{DC}, the internal temperature of the system. The gain factor for the system is

GF=½(T_{DC}*η_{DC}).

Thus, the GF for the system is an amplified energy that would allow one to get a DC control of the response (η_{DC}) and use it in an optical application for any device that requires modulation of the index of refraction, η, or the mediums that define the device to affect optical transmission or reflection.

The hysteretic systems described above in FIGS. 8A-15A (e.g. dielectric, magnetic, mechanical, chemical, biological, and optical) having asymmetry in its hysteresis loop generates an amplified effect when a periodic stimulus (ii) is applied to a biased hysteretic system. Other biased hysteretic systems may also include: electrical, thermal, acoustical, environmental, and astronomical. Although the electrical, thermal, acoustical, environmental and astronomical systems are not shown in a specific example, the application is not meant to be limited to only dielectric, magnetic, mechanical, chemical, biological, and optical systems, but rather for any biased hysteretic system having asymmetry in its hysteresis loop such that it may generate an amplified effect in response to a periodic stimulus (ii).

It should be understood that various alternatives to the embodiments of the invention described herein may be employed in practicing the invention. It is intended that the following claims define the scope of the invention and that the method and apparatus within the scope of these claims and their equivalents be covered thereby.

What is claimed is:

1. An asymmetrical hysteretic system, comprising:
a transponent;
a bias that externally grades the transponent;
an energy source that drives the transponent; and
a small stimulus amplified by a gain factor of the transponent.

2. The apparatus according to claim 1, wherein the energy source is defined by a periodic stimulus.

3. The apparatus according to claim 1, wherein the small stimulus is defined by an input signal.

4. The apparatus according to claim 1, wherein the gain factor is approximately one-half the quantity of a DC stimulus multiplied by a DC response.

5. The apparatus according to claim 1, wherein the transponent is a ferroelectric device.

6. The apparatus according to claim 5, wherein the bias is a DC bias offset.

7. The apparatus according to claim 5, wherein the energy source is a low-impedance alternating voltage source.

8. The apparatus according to claim 5, wherein the gain factor is approximately one-half the quantity of a DC active current multiplied by a DC flux.

9. The apparatus according to claim 1, wherein the transponent is a ferromagnetic device.

10. The apparatus according to claim 9, wherein the bias is an external magnetic field.

11. The apparatus according to claim 9, wherein the energy source is a low-impedance alternating voltage source.

12. The apparatus according to claim 9, wherein the gain factor is approximately one-half the quantity of a DC active current multiplied by a DC flux.

13. The apparatus according to claim 1, wherein the transponent is a mechanical switch defined by a toggle, a pivot point, and an internal bias spring.

14. The apparatus according to claim 13, wherein the bias is an externally biased accelerated motion.

15. The apparatus according to claim 13, wherein the energy source is an oscillating force produced by a motor.

16. The apparatus according to claim 13, wherein the gain factor is approximately one-half the quantity of a DC oscillating force multiplied by a DC angle of the internal bias spring.

17. The apparatus according to claim 1, wherein the transponent is a mass on a sloping surface.

18. The apparatus according to claim 17, wherein the bias is an externally biased accelerated motion.

19. The apparatus according to claim 17, wherein the energy source is an acceleration of gravity acting on the mass.

20. The apparatus according to claim 17, wherein the gain factor is approximately one-half the quantity of a DC angle of the mass on the slope multiplied by a DC vertical distance of the mass.

21. The apparatus according to claim 1, wherein the transponent is a mass including an oscillating pendulum on a level surface.

22. The apparatus according to claim 21, wherein the bias is an externally biased accelerated motion.

23. The apparatus according to claim 21, wherein the energy source is the oscillatory movement of the pendulum.

24. The apparatus according to claim 21, wherein the gain factor is approximately one-half the quantity of a DC angle of the pendulum multiplied by a DC movement of the mass.

25. The apparatus according to claim 1, wherein the transponent is a biological system defined by a unit of cells, a light source, and a hot plate.

26. The apparatus according to claim 25, wherein the bias is a temperature constant.

27. The apparatus according to claim 25, wherein the energy source is the light source.

28. The apparatus according to claim 25, wherein the gain factor is approximately one-half the quantity of a DC temperature of the hot plate multiplied by a DC fluorescence of the cells.

29. The apparatus according to claim 1, wherein the transponent is a chemical system defined by a first chemical, a second chemical, a hot plate, and an interface defined by a thickness.

30. The apparatus according to claim 29, wherein the bias is a temperature constant.

31. The apparatus according to claim 29, wherein the energy source is the temperature of the hot plate defined by a sinusoidal drive in temperature.

32. The apparatus according to claim 29, wherein the gain factor is approximately one-half the quantity of a DC temperature of the hot plate multiplied by a DC interface thickness.

33. The apparatus according to claim 1, wherein the transponent is an optical system defined by a first medium, a second medium, a miscible zone that determines an index of refraction, and an interface adjacent to a hot plate.

34. The apparatus according to claim 33, wherein the bias is a temperature constant.

35. The apparatus according to claim 33, wherein the energy source is the temperature of the hot plate defined by a sinusoidal drive in temperature.

36. The apparatus according to claim 33, wherein the gain factor is approximately one-half the quantity of a DC temperature of the hot plate multiplied by a DC index of refraction.

37. An asymmetrical hysteretic system, comprising:
a transponent;
a bias that externally grades the transponent an energy source defined by a periodic stimulus that drives the transponent; and
a small stimulus that is amplified by a gain factor of the transponent, wherein the gain factor is approximately one-half the quantity of a DC stimulus multiplied by a DC response.

38. The apparatus according to claim 37, wherein the transponent is a ferroelectric device.

39. The apparatus according to claim 38, wherein the bias is a DC bias offset.

40. The apparatus according to claim 38, wherein the energy source is a low-impedance alternating voltage source.

41. The apparatus according to claim 38, wherein the gain factor is approximately one-half the quantity of a DC active current multiplied by a DC flux.

42. The apparatus according to claim 37, wherein the transponent is a ferromagnetic device.

43. The apparatus according to claim 42, wherein the bias is an external magnetic field.

44. The apparatus according to claim 42, wherein the energy source is a low-impedance alternating voltage source.

45. The apparatus according to claim 42, wherein the gain factor is approximately one-half the quantity of a DC active current multiplied by a DC flux.

46. The apparatus according to claim 37, wherein the transponent is a mechanical switch defined by a toggle, a pivot point, and an internal bias spring.

47. The apparatus according to claim 46, wherein the bias is an externally biased accelerated motion.

48. The apparatus according to claim 46, wherein the energy source is an oscillating force produced by a motor.

49. The apparatus according to claim 46, wherein the gain factor is approximately one-half the quantity of a DC oscillating force multiplied by a DC angle of the internal bias spring.

50. The apparatus according to claim 37, wherein the transponent is a mass on a sloping surface.

51. The apparatus according to claim 50, wherein the bias is an externally biased accelerated motion.

52. The apparatus according to claim 50, wherein the energy source is an acceleration of gravity acting on the mass.

53. The apparatus according to claim 50, wherein the gain factor is approximately one-half the quantity of a DC angle of the mass on the slope multiplied by a DC vertical distance of the mass.

54. The apparatus according to claim 37, wherein the transponent is a mass including an oscillating pendulum on a level surface.

55. The apparatus according to claim 54, wherein the bias is an externally biased accelerated motion.

56. The apparatus according to claim 54, wherein the energy source is the oscillatory movement of the pendulum.

57. The apparatus according to claim 54, wherein the gain factor is approximately one-half the quantity of a DC angle of the pendulum multiplied by a DC movement of the mass.

58. The apparatus according to claim 37, wherein the transponent is a biological system defined by a unit of cells, a light source, and a hot plate.

59. The apparatus according to claim 58, wherein the bias is a temperature constant.

60. The apparatus according to claim 58, wherein the energy source is the light source.

61. The apparatus according to claim 58, wherein the gain factor is approximately one-half the quantity of a DC temperature of the hot plate multiplied by a DC fluorescence of the cells.

62. The apparatus according to claim 37, wherein the transponent is a chemical system defined by a first chemical, a second chemical, a hot plate, and an interface defined by a thickness.

63. The apparatus according to claim 62, wherein the bias is a temperature constant.

64. The apparatus according to claim 62, wherein the energy source is the temperature of the hot plate defined by a sinusoidal drive in temperature.

65. The apparatus according to claim 62, wherein the gain factor is approximately one-half the quantity of a DC temperature of the hot plate multiplied by a DC interface thickness.

66. The apparatus according to claim 37, wherein the transponent is an optical system defined by a first medium, a second medium, a miscible zone that determines an index of refraction, and an interface adjacent to a hot plate.

67. The apparatus according to claim 66, wherein the bias is a temperature constant.

68. The apparatus according to claim 66, wherein the energy source is the temperature of the hot plate defined by a sinusoidal drive in temperature.

69. The apparatus according to claim 66, wherein the gain factor is approximately one-half the quantity of a DC temperature of the hot plate multiplied by a DC index of refraction.

70. A method for generating an amplified effect for an asymmetrical hysteretic system, the asymmetrical hysteretic system comprising a transponent, a bias, a periodic stimulus, and a small stimulus, comprising the steps of:
grading the transponent with the bias;
driving the transponent with the periodic stimulus;
generating a gain factor in response to the periodic stimulus driving the transponent;
amplifying the small stimulus with the gain factor; and
producing an amplified output defined by the small stimulus and the gain factor.
